(19) United States
(12) Patent Application Publication
(10) Pub. No.: US 2016/0005705 A1
(43) Pub. Date: Jan. 7, 2016

(54) Structure and Method of Batch-Packaging Low Pin Count Embedded Semiconductor Chips

(71) Applicant: Texas Instruments Incorporated, Dallas, TX (US)

(72) Inventor: Mutsumi Masumoto, Beppu (JP)

(21) Appl. No.: 14/320,825

(22) Filed: Jul. 1, 2014

(51) Int. Cl. H01L 23/00; H01L 23/31; H01L 21/56; H01L 21/3105; H01L 21/78

(52) U.S. Cl. CPC H01L 24/14; H01L 24/83; H01L 24/11; H01L 21/31053; H01L 21/78; H01L 24/97; H01L 21/561; H01L 23/3171; H01L 2224/11826; H01L 2224/13666; H01L 2224/13684; H01L 2224/1367; H01L 2224/13671; H01L 2224/1368; H01L 2224/13644; H01L 2224/13647; H01L 2224/13639; H01L 2224/1181; H01L 2224/8385; H01L 2224/8389; H01L 2224/11825; H01L 2224/13681

(57) ABSTRACT

A method for fabricating packaged semiconductor devices in panel format. A flat panel sheet dimensioned for a set of contiguous chips includes a stiff substrate of an insulating plate, and a tape having a surface layer of a first adhesive releasable at elevated temperatures, a core base film, and a bottom layer with a second adhesive attached to the substrate. Attaching a set onto the first adhesive layer, the chip terminals having terminals with metal bumps facing away from the first adhesive layer. Laminating low CTE insulating material to fill gaps between the bumps and to form an insulating frame surrounding the set. Grinding lamination material to expose the bumps. Plasma-cleaning assembly, sputtering uniform metal layer across assembly, optionally plating metal layer, and patterning metal layer to form rerouting traces and extended contact pads.

### FIELD

Embodiments of the invention are related in general to the field of semiconductor devices and processes, and more specifically to the structure and fabrication method of batch-packaging low pin count embedded semiconductor chips.

### DESCRIPTION OF RELATED ART

It is common practice to manufacture the active and passive components of semiconductor devices into round wafers sliced from elongated cylinder-shaped single crystals of semiconductor elements or compounds. The diameter of these solid state wafers may reach up to 12 inches. Individual devices are then typically singulated from the round wafers by sawing streets in x- and y-directions through the wafer in order to create rectangularly shaped discrete pieces from the wafers; commonly, these pieces are referred to as die or chips. Each chip includes at least one device coupled with respective metallic contact pads. Semiconductor devices include many large families of electronic components; examples are active devices such as diodes and transistors like field-effect transistors, passive devices such as resistors and capacitors, and integrated circuits with sometimes far more than a million active and passive components.

After singulation, one or more chips are attached to a discrete supporting substrate such as a metal leadframe or a rigid multi-level substrate laminated from a plurality of metallic and insulating layers. The conductive traces of the leadframes and substrates are then connected to the chip contact pads, typically using bonding wires or metal bumps such as solder balls. For reasons of protection against environmental and handling hazards, the assembled chips may be encapsulated in discrete robust packages, which frequently employ hardened polymeric compounds and are formed by techniques such as transfer molding. The assembly and packaging processes are usually performed either on an individual basis or in small groupings such as a strip of leadframe or a loading of a mold press.

In order to increase productivity by a quantum jump and reduce fabrication cost, technical efforts have recently been initiated to re-think certain assembly and packaging processes with the goal to increase the volume handled by each batch process step. These efforts are generally summarized under the title panelization. As an example, adaptive patterning methods have been described for fabricating panel-based package structures. Other technical efforts are directed to keep emerging problems such as panel warpage under control.

### SUMMARY OF THE INVENTION

Applicant realized that successful methods and process flows for large-scale panels from sets of few contiguous chips to sets of larger numbers of contiguous chips, as intended for semiconductor packaging, have to resolve key technical challenges. Among these challenges are achieving planarity of panels and avoiding warpage and mechanical instability, extending the spacing of contact pads for easy connection to external parts, achieving low resistance connections and reaching high reliability backside chip connects, avoiding expensive laser process steps, especially through metal layers and epoxy layers, and improved thermal characteristics. For metallic seed layers, uniformity of the layers across the selected panel size should be achieved, yet electroless plating technology should be avoided.

Applicant solved the challenges when he discovered a process flow for a whole set of chips to embed the chips in the packages. The method uses adhesive tapes instead of epoxy chip attach procedures, re-usable carriers, and a sputtering methodology for replacing electroless plating. Furthermore, the new process technology is free of the need to use lasers. As a result, the new process flow preserves clean chip contact pads and processes a set of four chips concurrently, thus greatly increasing productivity. In addition, the packaged devices offer improved reliability. A key contributor to the enhanced reliability is reduced thermo-mechanical stress achieved by laminating gaps with insulating fillers having high modulus and a glass transition temperature for a coefficient of thermal expansion approaching the coefficient of silicon.

Applicant developed a sputtering technology with plasma-cleaned an cooled panels, which produces uniform sputtered metal layers across a panel and thus avoids the need for electroless plating. Since the sputtering procedure also serves to clean and roughen the substrate surface, the sputtered layers adhere equally well to dielectrics, silicon, and metals; they may be employed as connective traces, or may serve as seed layers for subsequent electro-plated metal layers.

One embodiment based on the modified processes can be applied to a set of contiguous chips with small numbers of terminals; it is a technical advantage that another embodiment lends itself to a plurality of sets of semiconductor chips. Many modified flows are applicable to any transistor or integrated circuit; other modified flows are particularly suitable for higher numbers of terminals. It is another technical advantage that some of the packaged devices offer flexibility with regard to the connection to external parts: they can be finished to be suitable as devices with land grid arrays, or as ball grid arrays, or as and QFN (Quad Flat No-Lead) terminals.

### BRIEF DESCRIPTION OF THE DRAWINGS

FIG. 1 shows a cross section of a re-usable carrier with a triple level adhesive tape as used by the invention.

FIG. 2 A is a cross section of the carrier of FIG. 1 illustrating the process of attaching a set of chips onto the top adhesive layer of the carrier.

FIG. 2B is a top view of the assembly illustrating the process of attaching a set of four chips onto the top adhesive layer of the carrier.

FIG. 3 shows a cross section of the assembly illustrating the process of laminating a polymeric filler material over the assembly.

FIG. 4A is a cross section of the assembly illustrating the process of grinding the filler material to exposed the bumped chip terminals.

FIG. 4B is a top view of the assembly illustrating the exposed bumped chip terminals after grinding the filler material.

FIG. 5A is a cross section of the assembly summarizing the processes of depositing and patterning at least one metal layer to form extended contact pads and reroute connections between pads and chip terminals.

FIG. 5B displays a top view of the deposited and patterned at least one metal layer forming extended contact pads and rerouted connections between pads and chip terminals.

FIG. 6A shows a cross section of the assembly depicting the process of depositing and pattering a protective insulator layer.

FIG. 6B is a top view of the assembly illustrating the assembly surface covered by the protective layer with openings for the expended contact pads.

FIG. 7A illustrates the process of singulating discrete devices from the packaged set, after the carrier has been separated.

FIG. 7B shows a top view of singulated packaged devices singulated from the set.

### DETAILED DESCRIPTION OF THE PREFERRED EMBODIMENTS

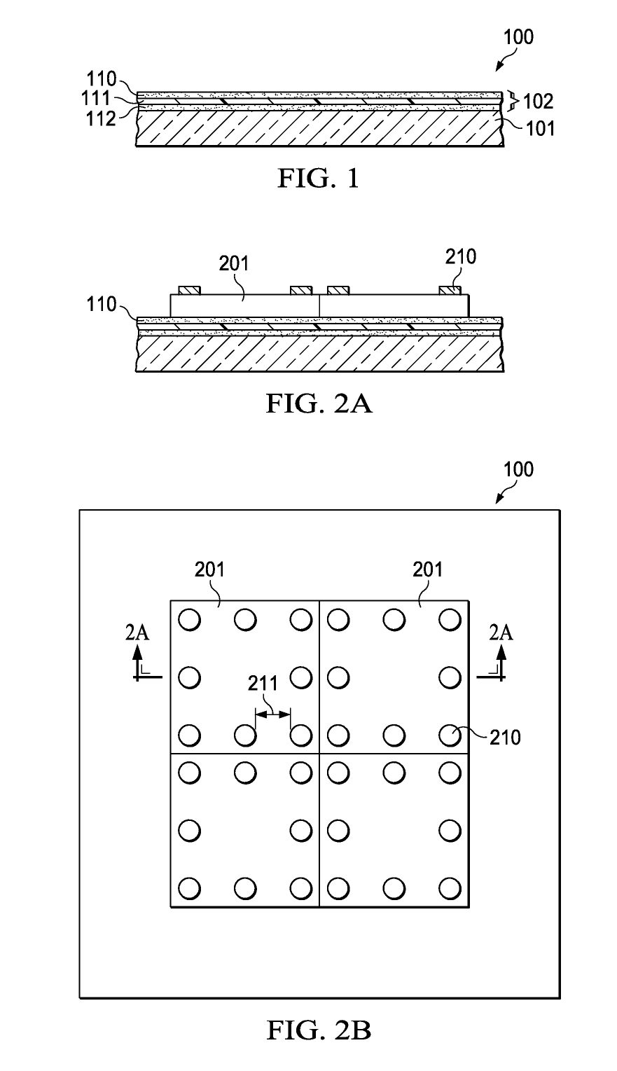

An embodiment of the invention is a method for fabricating packaged semiconductor devices in panel format, certain processes of which are illustrated in FIGS. 1 to 7B. The method starts in FIG. 1 by selecting a flat panel sheet as a rigid carrier generally designated 100. Carrier 100 includes a stiff substrate 101 and a tape 102. Substrate 101 is an insulating plate suitable to maintain panel flatness; substrate 101 may, for example, be made of glass or another stiff inorganic or organic material. Tape 102 comprises preferably a 3-layer tacky foil, which includes a surface layer 110 of a first adhesive releasable at elevated temperatures, a core base film 111, and a bottom layer 112 with a second adhesive. Bottom layer 112 is attached to the substrate 101. The composition of carrier 100 is such the carrier will not become permanent part of the final packaged device. Alternatively, carrier 100 may be endowed with a composition, which allows the incorporation of the panel in the final device package. The panel 100 has lateral dimensions suitable for a set of contiguous semiconductor chips; in the exemplary embodiment of FIGs.2A and 2B, panel 100 has lateral dimensions greater than four contiguous semiconductor integrated circuit chips arranged as a unit, i.e., four chips fabricated in single-crystalline silicon and not yet singulated.

The capability to process a set of four semiconductor chips as a single batch, enhances the productivity of the involved process steps fourfold.

FIGS. 2A and 2B show the process step of attaching a set of four contiguous semiconductor chips to first adhesive layer 110 of the dielectric tape 102 of carrier 100. FIG. 2B illustrates the set of four square-shaped chips arranged as a large-size square in order to take advantage of redesigning the contact pads in a symmetrical geometry. In more general terms, the chip set forms a rectangle with sidewalls. Alternatively, other unsymmetrical rearrangements are possible. In either case, the attachment process consists of a single step, as compared to multiple steps needed in conventional chip attachment (attachment of one chip at a time), demonstrating the significant increase of productivity.

FIGS. 2A and 2B of the exemplary embodiment illustrate that each chip has eight terminals on a chip surface; the terminals are preferably aligned in an orderly, even symmetrical arrangement. The Figures furthermore show that the terminals have metal bumps 210. The chips may have a thickness of about 150 μm, and preferred bumps include round or square copper pillars, and squashed copper balls (as formed by wire bonding technology). Bumps 210 of an individual chip are spaced from each other by gaps 211. The attached chips of the set are oriented so that the metal bumps 210 of the chip terminal pads face away from the panel surface.

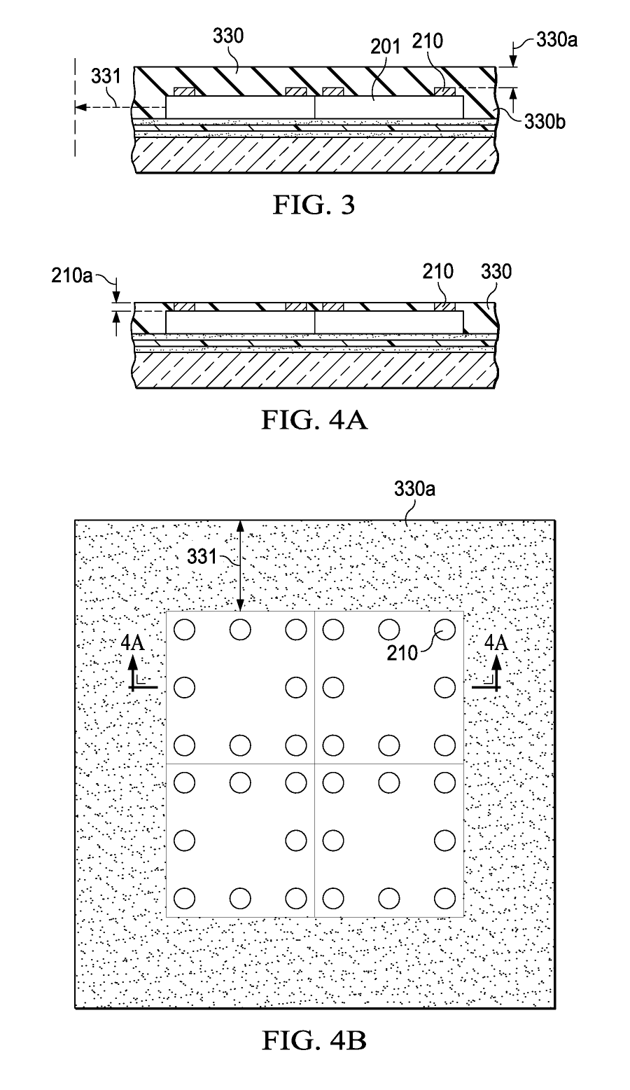

In the process step of FIG. 3, a compliant insulating material 330 is laminated, under vacuum suction, in order to cohesively fill any gaps 211 between the chip bumps and to cover the surfaces of chips 201 and bumps 210. Preferably, the height 330a of the laminated material over the bump tops is between about 15 μm and 50 μm. In addition, the insulating material forms a frame 330b surrounding the rectangle sidewalls. The width 331 of the frame includes the portion needed for providing the area available for supporting the plurality of rerouted contact pads in subsequent process steps. The compliant material is selected to have a high modulus and a low CTE approaching the CTE of the semiconductor chips; it may be glass filled and may include liquid crystal polymers.

In the next process step, depicted in FIGS. 4A and 4B, a grinding technology is used to grind the insulating lamination material 330 uniformly until the tops of the metal bumps 210 are exposed. The grinding process may continue by removing some bump height until bumps 210 are flat with the planar surface of lamination material 330; preferably, the remaining bump height 210a is between about 25 and 50 μm. Thereafter, carrier 100 is transferred, with its assembly, to the vacuum and plasma chamber of an apparatus for sputtering metals.

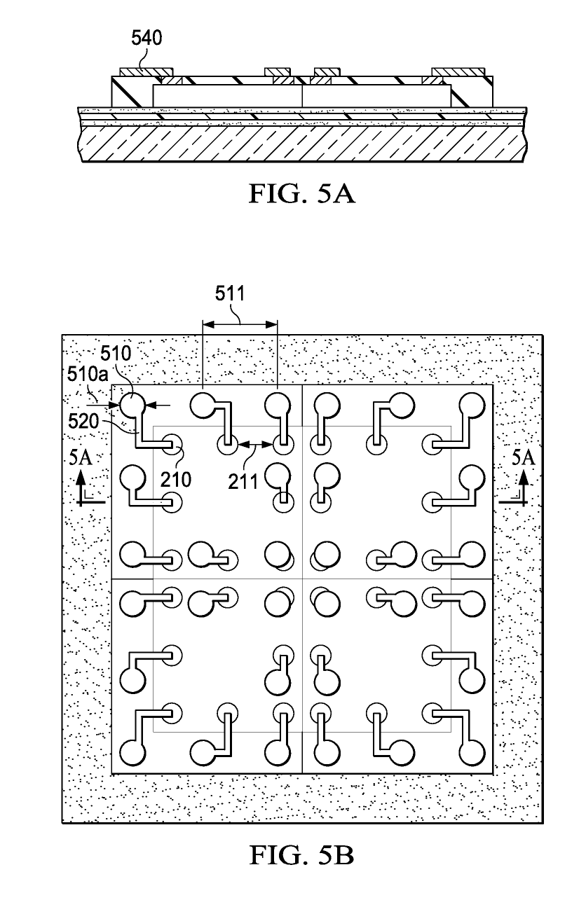

During the processes summarized in FIG. 5A and 5B, the assembly of carrier 100, with the exposed metal bumps and lamination surfaces, is plasma-cleaned, while the panel is cooled, preferably below ambient temperature. The plasma accomplishes, besides cleaning the surface from adsorbed films, especially water monolayers, some roughening of the surfaces; both effects enhance the adhesion of the sputtered metal layer. Then, at uniform energy and rate, at least one layer 540 of metal is sputtered onto the exposed bump and lamination surfaces across the carrier. The sputtered layer is adhering to the surfaces.

Preferably, the step of sputtering includes the sputtering of a first layer of a metal selected from a group including titanium, tungsten, tantalum, zirconium, chromium, molybdenum, and alloys thereof, wherein the first layer is adhering to chip and lamination surfaces; and without delay sputtering at least one second layer of a metal selected from a group including copper, silver, gold, and alloys thereof, onto the first layer, wherein the second layer is adhering to the first layer. The sputtered layers have the uniformity, strong adhesion, and low resistivity needed to serve, after patterning, as conductive traces for rerouting, see FIGS. 5A and 5B; the sputtered layers may also serve as seed metal for plated thicker metal layers.

In an optional step, at least one layer of metal is electroplated onto the sputtered layers 540. A preferred metal is copper. The plated layer is preferably thicker than the sputtered metal to lower the sheet resistance and thus the resistivity of the rerouting traces after patterning the plated and sputtered metal layers. The steps of patterning the sputtered and plated metal layers in order to create connecting traces between the bumps and enlarged package contact pads are preferably executed with a laser direct-imaging technology. The laser direct-imaging technology uses an out-alignment correcting technique.

In another optional step, one or more layers of solderable metal, such as tin, tin alloy, nickel followed by palladium, may be deposited.

The result of the metal layer patterning for rerouting and enlarged contact pads is illustrated in FIG. 5B. Compared to the original bumps 210 and their spacing 211, the new contact pads 510 benefit from the enlarged real estate by lamination (determined by frame width 331 in FIG. 3) and the customized rerouting. The new contact pads 510 have enlarged contact diameter 510a compared to the original bumps 210; they further have wider spacing 511 and a symmetrical layout. In addition, connecting traces 520 from the pads to the chip terminals with bumps are enabled, which benefit from customized layouts, but have only negligibly small increases in resistance and inductance thanks to the high conductivity of the sputtered and plated metal layers.

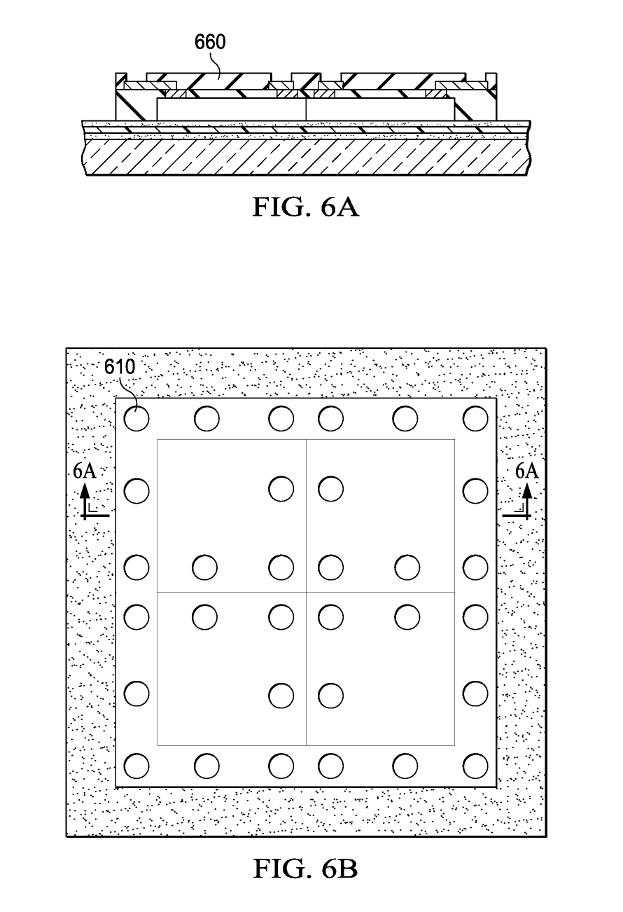

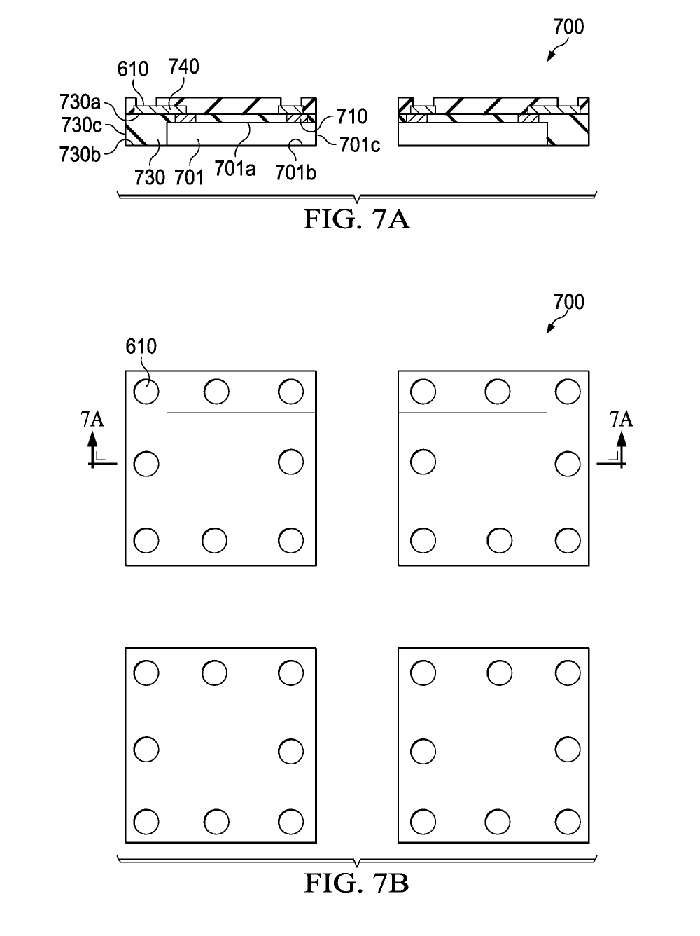

In addition, it is preferred, as shown in FIGS. 6A and 6B, to deposit and pattern rigid insulating material 660, such as so-called solder resist, to protect and strengthen remaining chip areas not used for extended contacts; in the preferred application of the rigid insulating protection, only the extended contact areas 610 remain exposed and open as windows. The contact areas may be round, as shown in FIG. 7B, or square. In order to apply solder resist and other dielectric materials, photo-imagable materials, etchants, and others, a preferred technique uses an ultrasonic spray tool. With the rigid protection of insulating material 660, the assembly of the package for the chip set is completed. Dependent on the configuration of the contact areas 610, they may be applied as ball grid arrays, land grid arrays, and QFN-type contact pads.

In the next process step, the temperature is raised so that the temperature-sensitive first adhesive of layer 110 allows to remove panel 110 (substrate 101 and tape 102) from the assembly of packaged chip set.

The next process step, illustrated in FIGS. 7A and 7B, the packaged chip set is singulated into discrete devices 700. The preferred separating technique is sawing. After singulation, respective parts 321 of carrier 320 remain with the finished packages of devices 370. For the exemplary devices 700 shown in FIG. 7A, the singulation of the chip set creates units, which have contact pads 610, sidewalls 730c with exposed insulating lamination 730, and sidewalls 701c with exposed silicon 701. The exposed silicon areas offer an good opportunity for heat spreading and thus help to improve the thermal device characteristics.

Another embodiment is an exemplary packaged semiconductor device 700. The device has a semiconductor chip 701 with a first surface 701a and a parallel second surface 701b. First surface 701 a has a plurality of terminals 710 with metal bumps such as copper pillars or copper squashed balls.

Device 700 has a frame of insulating material 730 adhering to at least one sidewall of the chip. The insulating material of the frame includes glass fibers impregnated with a gluey resin, which has a high modulus and a coefficient of thermal expansion (CTE) close to the CTE of silicon. Frame 730 has a first surface 730a planar with the insulating material between the bumps 710, and a parallel second surface 730b planar with the second chip surface 701b.

Device 700 further has at least one film 740 of sputtered metal extending from the bumps 710 across the surface 730a of the layer of insulating material close to the edge of the insulating frame. Film 740 is patterned to form extended contact pads 610 over the frame, and, wherever necessary, rerouting traces between the chip bumps 710 and the extended contact pads 610. Since film 740 has been created by sputtering, it is adhering to all the surfaces mentioned.

Dependent on the size, contour, and metallurgical configuration of the extended contact pads 610, they can be employed as ball grid array terminals, land grid array terminals, and QFN-type terminals.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, dependent on the size of the chip and the package, enough area can be utilized to lay out the redistributed contact pads for a considerably higher number of terminals than the eight contact pads discussed. As another example, for a set of four chips the configuration of chips as well as packages may be rectangular instead of square; the layout of the redistributed contact pads can be accommodated.

It is therefore intended that the appended claims encompass any such modifications or embodiments.

I claim:

1. A method for fabricating packaged semiconductor devices in panel format, comprising:
providing a flat panel sheet as a carrier including a stiff substrate of an insulating plate suitable to maintain panel flatness, and a tape having a surface layer of a first adhesive releasable at elevated temperatures, a core base film, and a bottom layer with a second adhesive, the bottom layer attached to the substrate, the panel having lateral dimensions suitable for a set of contiguous semiconductor chips;
attaching a set of contiguous semiconductor chips onto the first adhesive layer, the set forming a rectangle with sidewalls, the chip terminals having metal bumps facing away from the first adhesive layer;
laminating, under vacuum suction, a compliant insulating material to cohesively cover the chip terminal bumps and to fill gaps between the bumps, and to form an insulating frame surrounding the rectangle sidewalls, the material having a coefficient of thermal expansion approaching the coefficient of the semiconductor chips;
grinding lamination material uniformly until the tops of the metal bumps are exposed;
plasma-cleaning and cooling the panel and attached chip set in an equipment for sputtering metals; and
sputtering, at uniform energy and rate, at least one layer of metal onto the exposed lamination and terminal bumps, the layer adhering to the surfaces.

2. The method of claim 1 wherein sputtering includes the sputtering of a first layer of a metal selected from a group including titanium, tungsten, tantalum, zirconium, chromium, molybdenum, and alloys thereof, the first layer adhering to chip and lamination surfaces; and without delay sputtering at least one second layer of a metal selected from a group including copper, silver, gold, and alloys thereof, onto the first layer, the second layer adhering to the first layer.

3. The method of claim 2 further comprising:
plating and patterning a layer of the second metal onto the sputtered layer of the second metal;
plating a layer of solderable metal onto selected areas of the plated second metal;
stripping selected areas of the sputtered metal layers;
depositing and patterning insulating material over selected areas of the plated second metal;
removing the panel by raising the temperature to release the first adhesive; and
dicing the set of chips to singulate discrete devices.

4. A packaged semiconductor device comprising:
a semiconductor chip having a first surface with terminals including metal bumps, and a parallel second surface;
a frame of insulating material adhering to at least one sidewall of the chip, the frame having a first surface planar with the insulating material between the bumps, and a parallel second surface planar with the second chip surface; and
at least one film of sputtered metal extending from the bumps across the surface of the layer of insulating material to the edge of the insulating frame, the film patterned to form extended contact pads over the frame and rerouting traces between the chip bumps and the extended contact pads, the film adhering to the surfaces.

5. The device of claim 4 wherein the sputtered film includes a first layer of a metal selected from a group including titanium, tungsten, tantalum, zirconium, chromium, molybdenum, and alloys thereof, the first layer adhering to the chip terminals, polymeric surface, and frame surface; and at least one second layer of a metal selected from a group including copper, silver, gold, and alloys thereof, onto the first layer, the second layer adhering to the first layer.

6. The device of claim 5 further including at least one layer of plated metal adhering to the sputtered metals.

7. The device of claim 6 further including a patterned rigid material protecting exposed portions of the layer of insulating material and rerouting traces.

8. The device of claim 6 wherein the insulating material of the frame includes glass fibers impregnated with a gluey resin having a high modulus and a coefficient of thermal expansion (CTE) close to the CTE of silicon.

9. The device of claim 4 wherein the configuration and metallurgy of the extended contact pads are selected to be suitable to devices including land grid array devices, ball grid array devices, and Quad Flat No-Lead (QFN) devices.
